(19) United States
(12) Patent Application Publication
(10) Pub. No.: US 2024/0292578 A1
(43) Pub. Date: Aug. 29, 2024

(54) HEAT DISSIPATION DEVICE, ELECTRONIC DEVICE, AND ELECTRICITY-CONSUMPTION DEVICE

(71) Applicant: SHENZHEN RSPOWER TECHNOLOGY CO., LTD., Shenzhen (CN)

(72) Inventors: Liangyin GUO, Shenzhen (CN); Shaopeng GAN, Shenzhen (CN); Yati CHEN, Shenzhen (CN); Zhihao ZHAO, Shenzhen (CN)

(21) Appl. No.: 18/659,558

(22) Filed: May 9, 2024

Related U.S. Application Data
(63) Continuation of application No. PCT/CN2023/126182, filed on Oct. 24, 2023.

(30) Foreign Application Priority Data
Oct. 29, 2022 (CN) 202211340804.7

(51) Int. Cl. H05K 7/20

(52) U.S. Cl. CPC H05K 7/20927; H05K 7/20409

(57) ABSTRACT

The heat dissipation device includes a liquid-cooling plate and a heat-exchange fin. The liquid-cooling plate has a first surface, a second surface opposite to the first surface, and a first side surface connected to the first surface and the second surface, where the first surface is used for installing of electronic components, and the heat-exchange fin is disposed on the second surface. The liquid-cooling plate defines a cooling flow channel in the liquid-cooling plate, and defines a liquid inlet and a liquid outlet on the first side surface, where both the liquid inlet and the liquid outlet are in communication with the cooling flow channel.

### CROSS-REFERENCE TO RELATED APPLICATION(S)

This application is a continuation of International Application No. PCT/CN2023/126182, filed Oct. 24, 2023, which claims priority to Chinese Patent Application No. 202211340804.7, filed Oct. 29, 2022, the entire disclosures of both of which are hereby incorporated by reference.

### TECHNICAL FIELD

This disclosure relates to the field of heat dissipation, particularly to a heat dissipation device, an electronic device, and an electricity-consumption device.

### BACKGROUND

Some electronic devices, for example, radio frequency power supplies, have high requirements for heat dissipation due to their high power and high power consumption. Meanwhile, these electronic devices have high requirements for the environment, and generally these electronic devices are required to cause no air turbulence around these electronic devices. Therefore, heat dissipation for these electronic devices cannot be achieved solely through air-cooling. However, heat dissipation effect of currently existing heat dissipation devices for these electronic devices is poor, and the cost of these heat dissipation devices is high.

### SUMMARY

The present disclosure provides a heat dissipation device, an electronic device, and an electricity-consumption device.

In a first aspect, a heat dissipation device is provided in the disclosure. The heat dissipation device includes a liquid-cooling plate and a heat-exchange fin. The liquid-cooling plate has a first surface, a second surface opposite to the first surface, and a first side surface connected to the first surface and the second surface. The first surface is used for installing of electronic components, and the heat-exchange fin is disposed on the second surface. The liquid-cooling plate defines a cooling flow channel in the liquid-cooling plate, and defines a liquid inlet and a liquid outlet on the first side surface, where both the liquid inlet and the liquid outlet are in communication with the cooling flow channel.

In a second aspect, an electronic device is provided in the disclosure. The electronic device includes the heat dissipation device of the first aspect.

In a third aspect, an electricity-consumption device is provided in the disclosure. The electricity-consumption device includes the electronic device of the second aspect, and the electronic device is configured to perform waveform conversion and/or voltage conversion on a municipal alternating current (AC) power to provide electrical energy for the electricity-consumption device.

### BRIEF DESCRIPTION OF THE DRAWINGS

FIG. 1 is a schematic perspective structural view of a heat dissipation device in an embodiment of the disclosure.

FIG. 2 is a schematic perspective structural view of the heat dissipation device in an embodiment of the disclosure, viewed from another direction.

FIG. 3 is a cross-sectional view of FIG. 2, taken along line III-III.

FIG. 4 is an enlarged view of portion IV of FIG. 3.

FIG. 5 is a cross-sectional view of FIG. 2, taken along line V-V.

FIG. 6 is a schematic block diagram of an electronic device in an embodiment of the disclosure.

FIG. 7 is a schematic block diagram of an electricity-consumption device in an embodiment of the disclosure.

### DETAILED DESCRIPTION

The following will describe embodiments of the disclosure in detail, and examples of embodiments herein will be illustrated in the accompanying drawings, in which the same or similar reference numerals denote the same or similar components or components having the same or similar functions throughout the context. Embodiments described hereinafter with reference to the accompanying drawings are illustrative and intended for explaining, rather than limiting, the present disclosure.

In addition, terms “first”, “second” are only used for illustration and cannot be understood as explicitly or implicitly indicating relative importance or implicitly indicating the number of technical features referred to herein. Therefore, features limited by terms “first”, “second” can explicitly or implicitly include at least one of the features. In the context of the present disclosure, unless stated otherwise, “multiple” or “a plurality of” refers to “at least two”.

In the present disclosure, unless stated otherwise, the term “connection” and the like should be understood in broader sense. For example, “connection” may include a fixed connection, a detachable connection, or an integrated connection; “connection” may include a mechanical connection or an electrical connection; “connection” may include a direct connection, an indirect connection through a medium, or an interconnection between two components, or an interaction between two components. For those of ordinary skill in the art, the specific meaning of the above term in the present disclosure can be understood according to specific situations.

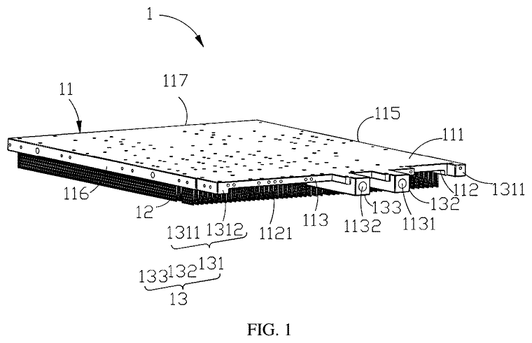

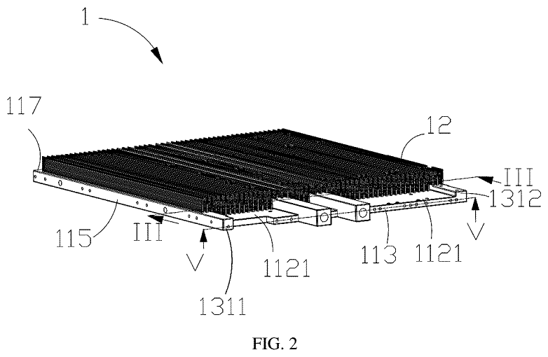

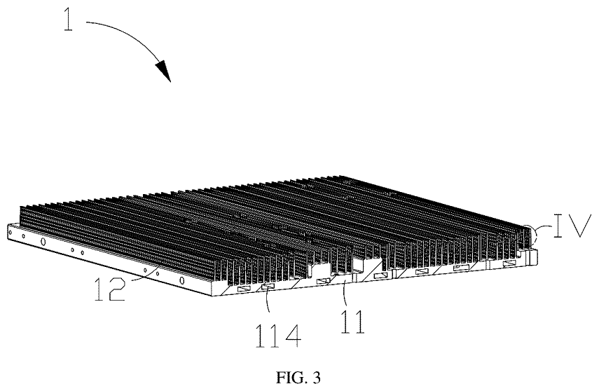

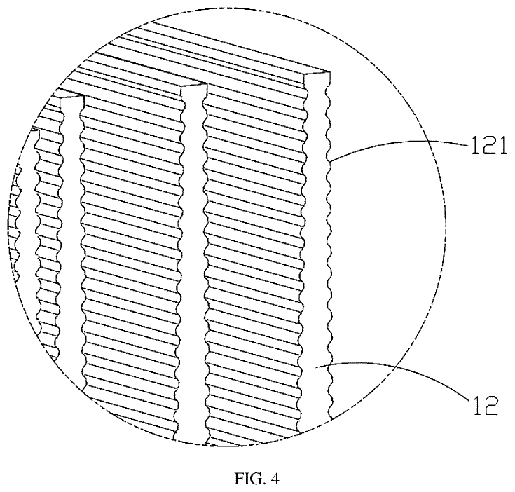

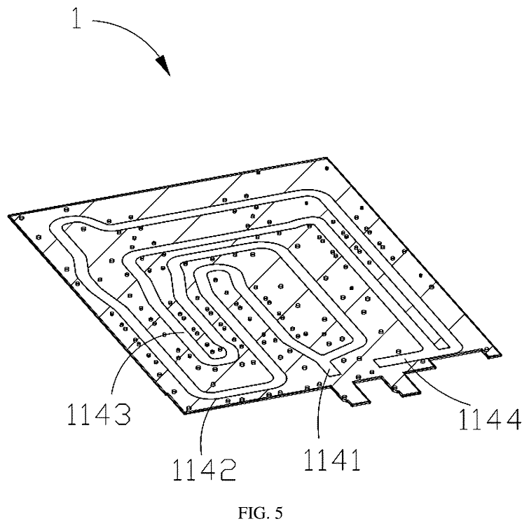

Reference is made to FIG. 1 and FIG. 2. FIG. 1 is a schematic perspective structural view of a heat dissipation device in an embodiment of the disclosure. FIG. 2 is a schematic perspective structural view of the heat dissipation device in an embodiment of the disclosure, viewed from another direction. A heat dissipation device 1 includes a liquid-cooling plate 11 and a heat-exchange fin 12. The liquid-cooling plate 11 has a first surface 111, a second surface 112 opposite to the first surface 111, and a first side surface 113 connected to the first surface 111 and the second surface 112. The first surface 111 is used for installing of electronic components, and the electronic components may include but are not limited to metal-oxide-semiconductor field-effect transistors (MOSFETs), diodes, inductors, voltage transformers and the like. The heat-exchange fin 12 is disposed on the second surface 112. Reference is made to FIG. 3, FIG. 4, and FIG. 5. The liquid-cooling plate 11 defines a cooling flow channel 114 in the liquid-cooling plate 11, and defines a liquid inlet 1131 and a liquid outlet 1132 on the first side surface 113, where the liquid inlet 1131 and the liquid outlet 1132 are both in communication with the cooling flow channel 114.

In the disclosure, the liquid-cooling plate 11 defines the cooling flow channel 114 in the liquid-cooling plate 11, and defines the liquid inlet 1131 and the liquid outlet 1132 on the first side surface 113, both the liquid inlet 1131 and the liquid outlet 1132 are in communication with the cooling flow channel 114, the cooling flow channel 114 dissipates heat generated by electronic components disposed on the liquid-cooling plate 11, and the heat-exchange fin 12 is disposed on the second surface 112. The heat-exchange fin 12 is configured to absorb heat around the heat-exchange fin 12 and conduct the heat to the cooling flow channel 114, and then heat dissipation is achieved by performing cooling by a cooling medium in the cooling flow channel 114, which has the function of liquid-cooling heat dissipation and the function of air-cooling temperature control, thereby further enhancing the heat dissipation capability of the heat dissipation device 1 for air around the heat dissipation device 1, simplifying the structure of the heat dissipation device 1, and lowering the cost of the heat dissipation device 1. Moreover, since the heat-exchange fin 12 can increase the structural strength of the heat dissipation device 1, the heat dissipation device 1 can be directly used for installing and bearing, with good performance and low cost.

Further, in an embodiment, a reinforcing portion 13 protrudes from the second surface 112. A region of the second surface 112 where the reinforcing portion 13 is not disposed is a first region 1121, and the heat-exchange fin 12 is disposed on the first region 1121 and a surface of the reinforcing portion 13.

In the disclosure, the reinforcing portion 13 protrudes from the second surface 112, the region of the second surface 112 where the reinforcing portion 13 is not disposed is the first region 1121, and the heat-exchange fin 12 is disposed on the first region 1121 and the surface of the reinforcing portion 13. In this way, a distribution area of the heat-exchange fin 12 is increased, and accordingly the structural strength is increased in some regions of the liquid-cooling plate, so that the liquid-cooling plate 11 may possess sufficient structural strength without being thicken as a whole. As a result, the weight of the heat dissipation device 1 as a whole may be reduced, thereby lowering the cost of the heat dissipation device 1 and reducing the burden of transferring the heat dissipation device 1.

Further, in an embodiment, the liquid-cooling plate 11 has a second side surface 115 and a third side surface 116. The second side surface 115 and the third side surface 116 are disposed opposite to each other and are respectively connected to two opposite ends of the first side surface 113. The reinforcing portion 13 includes a first reinforcing member 131, where the first reinforcing member 131 is disposed adjacent to at least one of the second side surface 115 or the third side surface 116, and the first reinforcing member 131 protrudes from the second surface 112 by a preset height.

Therefore, the first reinforcing member 131 may increase the structural strength of edges of the liquid-cooling plate 11, and thus the overall structural strength of the liquid-cooling plate 11 may be increased.

In the embodiment, the first reinforcing member 131 includes a first reinforcing strip 1311 and a second reinforcing strip 1312. The first reinforcing strip 1311 is disposed adjacent to the second side surface 115, extends in a direction parallel to the second side surface 115, and protrudes from the second surface 112 by a preset height. The second reinforcing strip 1312 is disposed adjacent to the third side surface 116, extends in a direction parallel to the third side surface 116, and protrudes from the second surface 112 by a preset height. Moreover, the second side surface 115 is disposed parallel to the third side surface 116, and an extending direction of the first reinforcing strip 1311 is parallel to an extending direction of the second reinforcing strip 1312.

In an embodiment, a height by which the first reinforcing strip 1311 protrudes from the second surface 112 is equal to a height by which the second reinforcing strip 1312 protrudes from the second surface 112. In other embodiments, the height by which the first reinforcing strip 1311 protrudes from the second surface 112 is not equal to the height by which the second reinforcing strip 1312 protrudes from the second surface 112.

In this way, the first reinforcing strip 1311 increases the structural strength of the second side surface 115, and the second reinforcing strip 1312 increases the structural strength of the third side surface 116. In addition, since the first reinforcing strip 1311 and the second reinforcing strip 1312 are disposed on edges of the liquid-cooling plate 11, installation holes may be defined on an outer side surface of the first reinforcing strip 1311 and an outer side surface of the second reinforcing strip 1312. Therefore, for the liquid-cooling plate 11, thickness in regions that need to be strengthened may be increased and thickness in most regions may be reduced, and thus the weight can be reduced and the cost can be lowered.

Further, in an embodiment, the extending direction of the first reinforcing strip 1311 and the extending direction of the second reinforcing strip 1312 are parallel to a direction of a central axis of the liquid inlet 1131. In an embodiment, the direction of the central axis of the liquid inlet 1131 is parallel to a direction of a central axis of the liquid outlet 1132.

Therefore, the liquid-cooling plate 11 as a whole is limited to be in the shape of a rectangle. The first reinforcing strip 1311 and the second reinforcing strip 1312 not only increase the structural strength of the liquid-cooling plate 11, but also facilitate the distribution and arrangement of electronic components on the first surface 111, thereby avoiding a waste of space and minimizing the overall size of the liquid-cooling plate 11 to the greatest extent possible.

Optionally, in other embodiments, the second side surface 115 is not parallel to the third side surface 116. For example, the structure of the liquid-cooling plate 11 may be a parallelogram structure, a trapezoidal structure, or other quadrilateral or polygonal structures other than the parallelogram structure and the trapezoidal structure. The first reinforcing strip 1311 extends in a direction parallel to the second side surface 115, and the second reinforcing strip 1312 extends in a direction parallel to the third side surface 116. As such, the first reinforcing strip 1311 and the second reinforcing strip 1312 define an included angle therebetween, resulting in that the extending direction of the first reinforcing strip 1311 intersects with the extending direction of the second reinforcing strip 1312.

The liquid-cooling plate 11 may be shaped into any desired shape according to needs, and in the case where the liquid-cooling plate 11 is shaped into any straight-line shape or curved-line shape, both the first reinforcing strip 1311 and the second reinforcing strip 1312 can increase the structural strength of the liquid-cooling plate 11, and reduction in the thickness of the liquid-cooling plate 11 in some regions and reduction in the cost of the liquid-cooling plate 11 can be achieved.

Optionally, in other embodiments, regardless of whether the second side surface 115 is inclined relative to the third side surface 116 or not, an extending direction of the first reinforcing member 131 may not be parallel to an extending direction of the second side surface 115 or an extending direction of the third side surface 116, but parallel to an extending direction of the liquid inlet 1131.

Therefore, the first reinforcing member 131 may be disposed on a corresponding position according to requirements for the structural strength of the liquid-cooling plate 11 in some regions, and it is not necessarily need to dispose the first reinforcing member 131 in such a way that the first reinforcing member 131 extends along the second side surface 115 and third side surface 116 of the liquid-cooling plate 11. In conclusion, what is needed is that the liquid-cooling plate 11 can possess sufficient structural strength.

Optionally, in other embodiments, the first reinforcing strip 1311 or the second reinforcing strip 1312 can be absent. Specifically, in an embodiment, in the case where the second reinforcing strip 1312 is absent, the first reinforcing member 131 only includes the first reinforcing strip 1311. In this case, the extending direction of the first reinforcing strip 1311 may be parallel to the direction of the central axis of the liquid inlet 1131 or there is an angle between the extending direction of the first reinforcing strip 1311 and the direction of the central axis of the liquid inlet 1131. In this embodiment, the first reinforcing strip 1311 extends along the second side surface 115 and the extending direction of the first reinforcing strip 1311 is parallel to the direction of the central axis of the liquid inlet 1131. In another embodiment, in the case where the first reinforcing strip 1311 is absent, the first reinforcing member 131 only includes the second reinforcing strip 1312. In this case, the extending direction of the second reinforcing strip 1312 may be parallel to the direction of the central axis of the liquid inlet 1131 and/or there is an angle between the extending direction of the second reinforcing strip 1312 and the direction of the central axis of the liquid inlet 1131. In this embodiment, the second reinforcing strip 1312 is parallel to the direction of the central axis of the liquid inlet 1131. The direction of the central axis of the liquid inlet 1131 is parallel to the direction of the central axis of the liquid outlet 1132.

Therefore, according to the requirements for the structural strength, it may be that there is only the first reinforcing strip 1311 or only the second reinforcing strip 1312, so as to further reduce the weight of the liquid-cooling plate 11 and lower the cost of the liquid-cooling plate 11.

It may be understood that, in other embodiments, the liquid-cooling plate 11 further includes a fourth side surface 117 disposed opposite to the first side surface 113. In this way, the first side surface 113, the second side surface 115, the fourth side surface 117, and the third side surface 116 cooperatively form the cube-shaped liquid-cooling plate 11. The first reinforcing member 131 further includes an edge-reinforcing strip disposed adjacent to the fourth side surface 117, thereby further increasing the overall structural strength of the liquid-cooling plate 11.

According to the requirements for the structural strength, the edge-reinforcing strip may be added to further increase the overall structural strength of the liquid-cooling plate 11.

Optionally, in an embodiment, reference is again made to FIG. 1 and FIG. 2, the reinforcing portion 13 includes a third reinforcing strip 132. The third reinforcing strip 132 is disposed on the second surface 112, the liquid inlet 1131 is defined on the third reinforcing strip 132, and an extending direction of the third reinforcing strip 132 is parallel to the direction of the central axis of the liquid inlet 1131.

Therefore, the third reinforcing strip 132 that can define the liquid inlet 1131 is added, and due to the thickness of the third reinforcing strip 132, the third reinforcing strip 132 has enough space for defining the liquid inlet 1131. In this way, the liquid inlet 1131 and the liquid-cooling plate 11 are integrally formed, and an additional welding process or an additional inlet joint is not needed, thereby reducing the risk of liquid leakage. If the liquid inlet 1131 and the liquid-cooling plate 11 are not integrally formed, an inlet joint may need to be manufactured independently and then a connection process or a welding process may be performed on the inlet joint, or a thicker plate may be needed, which may cause increase in weight and thermal resistance of the liquid-cooling plate 11.

Further, in an embodiment, the third reinforcing strip 132 protrudes from the first side surface 113 by a preset height, which is conducive for connection to an external liquid inlet tube.

Optionally, in an embodiment, the reinforcing portion 13 includes a fourth reinforcing strip 133. The fourth reinforcing strip 133 is disposed on the second surface 112, the liquid outlet 1132 is defined on the fourth reinforcing strip 133, and an extending direction of the fourth reinforcing strip 133 is parallel to the direction of the central axis of the liquid outlet 1132.

Therefore, the fourth reinforcing strip 133 that can define the liquid outlet 1132 is added, and due to the thickness of the fourth reinforcing strip 133, the fourth reinforcing strip 133 has enough space for defining the liquid outlet 1132. In this way, the liquid outlet 1132 and the liquid-cooling plate 11 are integrally formed, and an additional welding process or an additional outlet joint is not needed, thereby reducing the risk of liquid leakage. If the liquid outlet 1132 and the liquid-cooling plate 11 are not integrally formed, an outlet joint may need to be manufactured independently and then a connection process or a welding process may be performed on the outlet joint, or a thicker plate may be needed, which may cause increase in weight and thermal resistance of the liquid-cooling plate 11.

Further, in an embodiment, the fourth reinforcing strip 133 protrudes from the first side surface 113 by a preset height, which is conducive for connection to an external liquid outlet tube.

Optionally, in an embodiment, the central axis of the liquid inlet 1131 is parallel to the central axis of the liquid outlet 1132.

Therefore, a direction in which liquid flows to the cooling flow channel 114 is parallel to a direction in which liquid flow outside from the cooling flow channel 114, which is conducive for machining, and conducive for installing of a liquid inlet tube and a liquid outlet tube.

Optionally, in an embodiment, an extending direction of the heat-exchange fin 12 is parallel to the direction of the central axis of the liquid inlet 1131 and the direction of the central axis of the liquid outlet 1132.

Therefore, the extending direction of the heat-exchange fin 12 is substantially the same as an extending direction of the cooling flow channel 114. The heat absorbed by the heat-exchange fin 12 may be conducted to the liquid-cooling plate 11 through the heat-exchange fin 12, and the heat may be taken away through the flowing of a coolant in the cooling flow channel 114, and thus air around the heat-exchange fin 12 may be cooled fast.

Optionally, in an embodiment, a portion of the heat-exchange fin 12 disposed on the reinforcing portion 13 is flush with an end of a portion of the heat-exchange fin 12 disposed on the first region 1121, where the end of the portion of the heat-exchange fin 12 on the first region 1121 is away from the liquid-cooling plate 11.

That is, a sum of a height of the portion of the heat-exchange fin 12 disposed on the reinforcing portion 13 and a height by which the reinforcing portion 13 protrudes from the second surface 112 is equal to a height of the portion of the heat-exchange fin 12 disposed on the first region 1121.

The reinforcing portion 13 increases the overall structural strength of the liquid-cooling plate 11, and by means of that the heat-exchange fin 12 is disposed on the reinforcing portion 13 and the second surface 112, the distribution area of the heat-exchange fin 12 is increased, thereby enhancing the heat dissipation capability.

In an embodiment, there are multiple heat-exchange fins 12 that are parallel to each other and spaced apart from each other. Each two adjacent heat-exchange fins 12 are spaced apart at equal intervals. An air duct is formed between heat-exchange fins 12, and when air flows through the air duct, the heat carried by air may be absorbed by the heat-exchange fins 12 at a corresponding position. It may be understood that, in other embodiments, each two adjacent heat-exchange fins 12 may be spaced apart at different intervals.

In an embodiment, reference is made to FIG. 4, multiple protruding ridges 121 are disposed on the heat-exchange fin 12, where an extending direction of each protruding ridge 121 is the same as the extending direction of the heat-exchange fin 12. The shape of the protruding ridge 121 may be but is not limited to a semicircular shape, a triangular shape, a square wave shape, a circular arc shape, and the like. Compared with a heat-exchange fin in a shape of a straight plate, the heat dissipation area of the heat-exchange fin 12 can be increased with aid of the protruding ridge 121.

In an embodiment, the heat-exchange fin 12 gradually becomes thinner from a side of the heat-exchange fin 12 close to the liquid-cooling plate 11 to a side of the heat-exchange fin 12 away from the liquid-cooling plate 11, thereby reducing wind resistance.

In an embodiment, the heat-exchange fin 12 and the liquid-cooling plate 11 are integrally formed. Specifically, the liquid-cooling plate 11 includes a liquid-cooling-plate main body and a top cover plate, and the liquid-cooling-plate main body and the heat-exchange fin 12 as a whole are integrally molded by injecting liquid into a mold. In this way, the integrity between the heat-exchange fin 12 and the liquid-cooling plate 11 may be increased. Then mechanical machining is performed on the liquid-cooling-plate main body to form flow channels, the top cover plate is then placed over the liquid-cooling-plate main body, and the liquid-cooling-plate main body and the top cover plate are fixed together by welding. The liquid-cooling-plate main body and the top cover plate cooperatively form the liquid-cooling plate 11.

In an embodiment, the liquid-cooling plate 11 and the heat-exchange fin 12 are both made of, but are not limited to, thermally conductive metallic material or thermally conductive non-metallic material. The thermally conductive metallic material may include, but is not limited to, aluminum alloy and the like.

In this embodiment, in the case where the liquid-cooling plate 11 and the heat-exchange fin 12 as a whole are made of aluminum alloy, the liquid-cooling-plate main body and the heat-exchange fin 12 are formed by extruding aluminum in a molten state. The top cover plate and the liquid-cooling-plate main body are welded together to form the sealed cooling flow channel 114 that is located inside the liquid-cooling plate 11.

In an embodiment, reference is made to FIG. 5, the structure of the cooling flow channel 114 is a parallel structure. That is, the cooling flow channel 114 is formed by a main flow channel 1141, a first tributary channel 1142, a second tributary channel 1143, and a confluence channel 1144. The first tributary channel 1142 and the second tributary channel 1143 form a parallel structure, which can effectively reduce flow resistance and temperature difference.

In an embodiment, a distribution density of the cooling flow channel 114 in a region of the first surface 111 is in proportion to an amount of heat generated by electronic components in the region of the first surface 111. That is, the cooling flow channel 114 may pass through a bottom of each electronic component having a high heating power, so that a temperature rise of the electronic component can be effectively controlled.

It may be understood that, in other embodiments, the structure of the cooling flow channel 114 is a series structure. That is, the cooling flow channel 114 may include no tributary channel.

In an embodiment, turbulent teeth are disposed spaced apart from each other inside the cooling flow channel 114. The turbulent teeth can increase a heat transfer coefficient between the coolant and the liquid-cooling plate 11 and reduce the temperature rise of the electronic components.

It may be understood that, the case that two objects are parallel to each other or extend in a same direction refers to that two objects are parallel within an allowable error range, as certain manufacturing errors are allowed to exist.

It may be understood that, in other embodiments, the position of the liquid inlet 1131 may be swapped with the position of the liquid outlet 1132.

In may be understood that, in other embodiments, an avoidance portion may be disposed on some regions of the heat-exchange fin 12, for installing of other components.

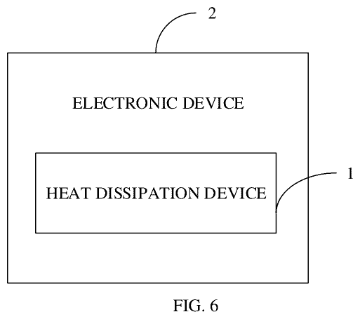

Reference is made to FIG. 6, the disclosure further provides an electronic device 2, and the electronic device 2 includes the heat dissipation device 1 mentioned above. The electronic device 2 may be but is not limited to a radio frequency power supply or other electronic devices requiring heat dissipation. In an embodiment, the radio frequency power supply is used to covert a municipal alternating current (AC) power into a power with a specific waveform or a specific voltage.

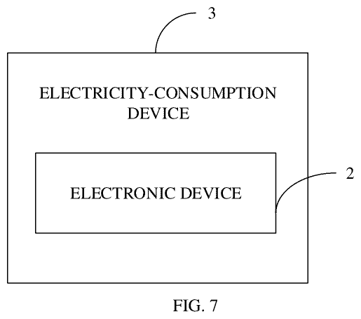

Reference is made to FIG. 7, the disclosure further provides an electricity-consumption device 3, and the electricity-consumption device 3 includes the electronic device 2. The electronic device 2 is configured to perform waveform conversion and/or voltage conversion on a municipal AC power to provide electrical energy for the electricity-consumption device 3. In an embodiment, the electricity-consumption device 3 may be but is not limited to a coating device.

The technical solution to the subject matter of the present disclosure and corresponding details are described above, and it may be understood that the above illustration is only some embodiments of the technical solution to the subject matter of the disclosure, and some of the details may be omitted in specific embodiments.

In addition, embodiments of the disclosure described above may be combined with each other, which will not be elaborated herein to avoid unnecessary repetition. During specific application, those of ordinary skill in the art may combine the embodiments according to demand, in order to better apply the embodiments into use.

In conclusion, it can be inferred that the disclosure possesses the excellent characteristics described above, which enables the disclosure to enhance efficiency in use that has not been achieved in previous technologies and to become a highly practical product.

The above are merely preferred embodiments of the disclosure and are not intended to limit the disclosure. Any modification, equivalent arrangements, and improvement made within the spirit and principles of the disclosure shall be included in the scope of protection of the disclosure.

What is claimed is:

1. A heat dissipation device, comprising:
a liquid-cooling plate, wherein the liquid-cooling plate has a first surface, a second surface opposite to the first surface, and a first side surface connected to the first surface and the second surface, wherein the first surface is used for installing of electronic components; the liquid-cooling plate defines a cooling flow channel in the liquid-cooling plate, and defines a liquid inlet and a liquid outlet on the first side surface, wherein both the liquid inlet and the liquid outlet are in communication with the cooling flow channel; and
a heat-exchange fin disposed on the second surface.

2. The heat dissipation device of claim 1, wherein a reinforcing portion protrudes from the second surface, a region of the second surface where the reinforcing portion is not disposed is a first region, and the heat-exchange fin is disposed on the first region and a surface of the reinforcing portion.

3. The heat dissipation device of claim 2, wherein
the liquid-cooling plate has a second side surface and a third side surface, wherein the second side surface and the third side surface are disposed opposite to each other and are respectively connected to two opposite ends of the first side surface; and
the reinforcing portion comprises a first reinforcing member, wherein the first reinforcing member is disposed adjacent to at least one of the second side surface or the third side surface, and the first reinforcing member protrudes from the second surface by a preset height.

4. The heat dissipation device of claim 3, wherein a central axis of the liquid inlet is parallel to a central axis of the liquid outlet, and an extending direction of the first reinforcing member is parallel to the central axis of the liquid inlet and the central axis of the liquid outlet.

5. The heat dissipation device of claim 2, wherein
the reinforcing portion comprises a third reinforcing strip, the third reinforcing strip is disposed on the second surface, the liquid inlet is defined in the third reinforcing strip, and an extending direction of the third reinforcing strip is parallel to the central axis of the liquid inlet; and/or
the reinforcing portion comprises a fourth reinforcing strip, the fourth reinforcing strip is disposed on the second surface, the liquid outlet is defined in the fourth reinforcing strip, and an extending direction of the fourth reinforcing strip is parallel to the central axis of the liquid outlet.

6. The heat dissipation device of claim 2, wherein a portion of the heat-exchange fin disposed on the reinforcing portion is flush with an end of a portion of the heat-exchange fin disposed on the first region, wherein the end of the portion of the heat-exchange fin on the first region is away from the liquid-cooling plate.

7. The heat dissipation device of claim 1, wherein a central axis of the liquid inlet is parallel to a central axis of the liquid outlet, and an extending direction of the heat-exchange fin is parallel to the central axis of the liquid inlet and the central axis of the liquid outlet.

8. The heat dissipation device of claim 1, wherein a plurality of protruding ridges are disposed on the heat-exchange fin, an extending direction of each of the plurality of protruding ridges is the same as an extending direction of the heat-exchange fin, and the plurality of protruding ridges are configured to increase a heat dissipation area of the heat-exchange fin.

9. The heat dissipation device of claim 1, wherein the cooling flow channel has a parallel structure or a series structure, and a distribution density of the cooling flow channel in a region of the first surface is in proportion to an amount of heat generated by electronic components in the region of the first surface.

10. The heat dissipation device of claim 1, wherein turbulent teeth are disposed spaced apart from each other inside the cooling flow channel.

11. An electronic device, comprising a heat dissipation device installed in the electronic device, wherein the heat dissipation device comprises:
a liquid-cooling plate, wherein the liquid-cooling plate has a first surface, a second surface opposite to the first surface, and a first side surface connected to the first surface and the second surface, wherein the first surface is used for installing of electronic components; the liquid-cooling plate defines a cooling flow channel in the liquid-cooling plate, and defines a liquid inlet and a liquid outlet on the first side surface, wherein both the liquid inlet and the liquid outlet are in communication with the cooling flow channel; and
a heat-exchange fin disposed on the second surface.

12. The electronic device of claim 11, wherein a reinforcing portion protrudes from the second surface, a region of the second surface where the reinforcing portion is not disposed is a first region, and the heat-exchange fin is disposed on the first region and a surface of the reinforcing portion.

13. The electronic device of claim 12, wherein the liquid-cooling plate has a second side surface and a third side surface, wherein the second side surface and the third side surface are disposed opposite to each other and are respectively connected to two opposite ends of the first side surface; the reinforcing portion comprises a first reinforcing member, wherein the first reinforcing member is disposed adjacent to at least one of the second side surface or the third side surface, and the first reinforcing member protrudes from the second surface by a preset height.

14. The electronic device of claim 13, wherein a central axis of the liquid inlet is parallel to a central axis of the liquid outlet, and an extending direction of the first reinforcing member is parallel to the central axis of the liquid inlet and the central axis of the liquid outlet.

15. The electronic device of claim 12, wherein
the reinforcing portion comprises a third reinforcing strip, the third reinforcing strip is disposed on the second surface, the liquid inlet is defined in the third reinforcing strip, and an extending direction of the third reinforcing strip is parallel to the central axis of the liquid inlet; and/or
the reinforcing portion comprises a fourth reinforcing strip, the fourth reinforcing strip is disposed on the second surface, the liquid outlet is defined in the fourth reinforcing strip, and an extending direction of the fourth reinforcing strip is parallel to the central axis of the liquid outlet.

16. The electronic device of claim 12, wherein a portion of the heat-exchange fin disposed on the reinforcing portion is flush with an end of a portion of the heat-exchange fin disposed on the first region, wherein the end of the portion of the heat-exchange fin on the first region is away from the liquid-cooling plate.

17. The electronic device of claim 11, wherein a central axis of the liquid inlet is parallel to a central axis of the liquid outlet, and an extending direction of the heat-exchange fin is parallel to the central axis of the liquid inlet and the central axis of the liquid outlet.

18. The electronic device of claim 11, wherein a plurality of protruding ridges are disposed on the heat-exchange fin, an extending direction of each of the plurality of protruding ridges is the same as an extending direction of the heat-exchange fin, and the plurality of protruding ridges are configured to increase a heat dissipation area of the heat-exchange fin.

19. The electronic device of claim 11, wherein the cooling flow channel has a parallel structure or a series structure, and a distribution density of the cooling flow channel in a region of the first surface is in proportion to an amount of heat generated by electronic components in the region of the first surface.

20. An electricity-consumption device, comprising an electronic device, wherein the electronic device is configured to perform waveform conversion and/or voltage conversion on a municipal alternating current (AC) power to provide electrical energy for the electricity-consumption device, and the electronic device comprises a heat dissipation device installed in the electronic device, wherein
the heat dissipation device comprises:
a liquid-cooling plate, wherein the liquid-cooling plate has a first surface, a second surface opposite to the first surface, and a first side surface connected to the first surface and the second surface, wherein the first surface is used for installing of electronic components; the liquid-cooling plate defines a cooling flow channel in the liquid-cooling plate, and defines a liquid inlet and a liquid outlet on the first side surface, wherein both the liquid inlet and the liquid outlet are in communication with the cooling flow channel; and
a heat-exchange fin disposed on the second surface.
